(19) United States
(12) Patent Application Publication
(10) Pub. No.: US 2014/0038347 A1
(43) Pub. Date: Feb. 6, 2014

(54) MANUFACTURING METHOD OF ELECTRODE OF SOLAR CELL

(71) Applicant: TOPCELL SOLAR INTERNATIONAL CO., LTD., Taoyuan County (TW)

(72) Inventor: Po-Sheng Huang, Tainan City (TW)

(73) Assignee: TOPCELL SOLAR INTERNATIONAL CO., LTD., Taoyuan County (TW)

(21) Appl. No.: 14/048,049

(22) Filed: Oct. 8, 2013

Related U.S. Application Data
(62) Division of application No. 13/241,243, filed on Sep. 23, 2011.

(30) Foreign Application Priority Data
May 12, 2011 (TW) 100116700

(51) Int. Cl. H01L 31/18; H01L 31/0224

(52) U.S. Cl. CPC H01L 31/18; H01L 31/022433
USPC 438/98

(57) ABSTRACT

A manufacturing method of an electrode of a solar cell is provided. The manufacturing method of the electrode of the solar cell includes following steps. A laser doping process is performed to form a selective emitter on a substrate. A laser marking process is performed to form alignment markers on the substrate. The laser doping process and the laser marking process are performed in a same process chamber. An electrode screen printing process is performed to form an electrode on the selective emitter according to the alignment markers. Relative displacement between the alignment markers and the laser doping area (the selective emitter) is avoided so as to reduce the error of the subsequent screen printing process.

### CROSS-REFERENCE TO RELATED APPLICATION

This application is a divisional of and claims the priority benefit of U.S. application Ser. No. 13/241,243 filed on Sep. 23, 2011, now pending, which claims the priority benefit of Taiwan application serial no. 100116700, filed on May 12, 2011. The entirety of each of the above-mentioned patent applications is hereby incorporated by reference herein and made a part of specification.

### BACKGROUND OF THE INVENTION

1. Field of the Invention

The invention relates to a method and an apparatus for manufacturing a photoelectric device. Particularly, the invention relates to a method and an apparatus for manufacturing an electrode of a solar cell.

2. Description of Related Art

Solar energy is non-polluting and inexhaustible energy, which is always a focus of attention when problems of pollution and shortage of petroleum energy are encountered. Since a solar cell can directly convert the solar energy into electric power, it becomes a very important research topic.

A silicon-based solar cell is a commonly used solar cell in the art, and a principle of the silicon-based solar cell is to add some dopants to a semiconductor material (silicon) with a high-purity to achieve different properties, so as to form a p-type semiconductor and an n-type semiconductor, and the p-type and the n-type semiconductors are combined to form a p-n junction. The p-n junction is formed by positive donor ions and negative receptor ions, and a built-in potential exists in the region of the positive and negative ions. The built-in potential can drive movable carriers in such region, so that such region is referred to as a depletion region. When the sunlight irradiates the semiconductor of a p-n structure, energy carried by photons can probably stimulate electrons in the semiconductor to generate electron-hole pairs. The electrons and the holes are all influenced by the built-in potential, wherein the holes move towards a direction of an electric field, and the electrons move towards an opposite direction. If the solar cell and a load are connected through a lead to form a loop, currents can flow through the load, and this is a power generation principle of the solar cell. If the solar cell is required to be ameliorated, it is better to improve the photoelectric conversion efficiency thereof.

Presently, a selective emitter solar cell is developed. In the selective emitter solar cell, a heavy doping area is formed under a metal contact (electrode) of a front surface of the solar cell to improve the photoelectric conversion efficiency.

During fabrication of the selective emitter solar cell, a laser doping process is used in collaboration with a screen printing process to from a selective emitter and the metal contacts (electrode). However, after the laser doping process, a laser doping area on a substrate is not obviously different to other non-laser doping areas, so that during the subsequent screen printing process, it is hard to implement alignment to correctly form the metal contacts on the laser doping area. Moreover, if alignment marks are formed in other processes, error of the screen printed metal contacts is increased due to relative displacement between the alignment markers and the laser doping area.

### SUMMARY OF THE INVENTION

The invention is directed to a method and an apparatus for manufacturing an electrode of a solar cell, by which relative displacement between alignment markers and a laser doping area is avoided to reduce error of a subsequent screen printing process.

The invention provides a method for manufacturing an electrode of a solar cell, which includes following steps. A laser doping process is performed to form a selective emitter on a substrate. A laser marking process is performed to form an alignment marker on the substrate. The laser doping process and the laser marking process are performed in a same processing chamber. An electrode screen printing process is performed to form an electrode on the selective emitter according to the alignment marker.

In an embodiment of the invention, the laser doping process is performed before the laser marking process is performed.

In an embodiment of the invention, the laser doping process is performed after the laser marking process is performed.

In an embodiment of the invention, the laser doping process and the laser marking process are simultaneously performed.

In an embodiment of the invention, the alignment marker is formed at a peripheral region of the substrate.

In an embodiment of the invention, the alignment marker is formed on the selective emitter.

The invention provides an apparatus for manufacturing an electrode of a solar cell, which has a processing chamber, a laser light emitting device and a control device. The laser light emitting device is disposed in the processing chamber. The control device is connected to the laser light emitting device to control the laser light emitting device to perform a laser doping process and a laser marking process in the processing chamber.

In an embodiment of the invention, the control device controls the laser light emitting device to first perform the laser marking process and then perform the laser doping process.

In an embodiment of the invention, the control device controls the laser light emitting device to first perform the laser doping process and then perform the laser marking process.

In an embodiment of the invention, the control device controls the laser light emitting device to simultaneously perform the laser marking process and the laser doping process.

In an embodiment of the invention, the laser light emitting device performs the laser doping process to form a selective emitter on a substrate. Moreover, the laser light emitting device performs the laser marking process to form an alignment marker on the substrate.

In an embodiment of the invention, the laser light emitting device performs the laser marking process to form the alignment marker at a peripheral region of the substrate.

In an embodiment of the invention, the laser light emitting device performs the laser marking process to form the alignment marker on the selective emitter.

In an embodiment of the invention, the laser light emitting device has a doping laser device and a marking laser device. The doping laser device is used to emit a doping laser light to perform the laser doping process. The marking laser device is used to emit a marking laser light to perform the laser marking process.

According to the above descriptions, in the method and the apparatus for manufacturing the electrode of the solar cell, relative displacement between the alignment marker and the laser doping area (selective emitter) is avoided so as to reduce the error of the subsequent screen printing process.

Moreover, by forming the alignment markers on the laser doping area, since a surface light shielding area of the solar cell is not increased, the photoelectric conversion efficiency of the solar cell is not decreased.

In addition, the method for manufacturing the electrode of the solar cell is simple, which may avails increasing a production yield.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a three-dimensional view of an apparatus for manufacturing an electrode of a solar cell according to an embodiment of the invention.

FIG. 2 is a cross-sectional view of the apparatus for manufacturing an electrode of a solar cell according to an embodiment of the invention.

FIG. 3A is a top view of a solar cell according to an embodiment of the invention.

FIG. 3B is a top view of a solar cell according to another embodiment of the invention.

FIGS. 4A-4D are diagrams illustrating a method for manufacturing an electrode of a solar cell according to an embodiment of the invention.

### DETAILED DESCRIPTION OF DISCLOSED EMBODIMENTS

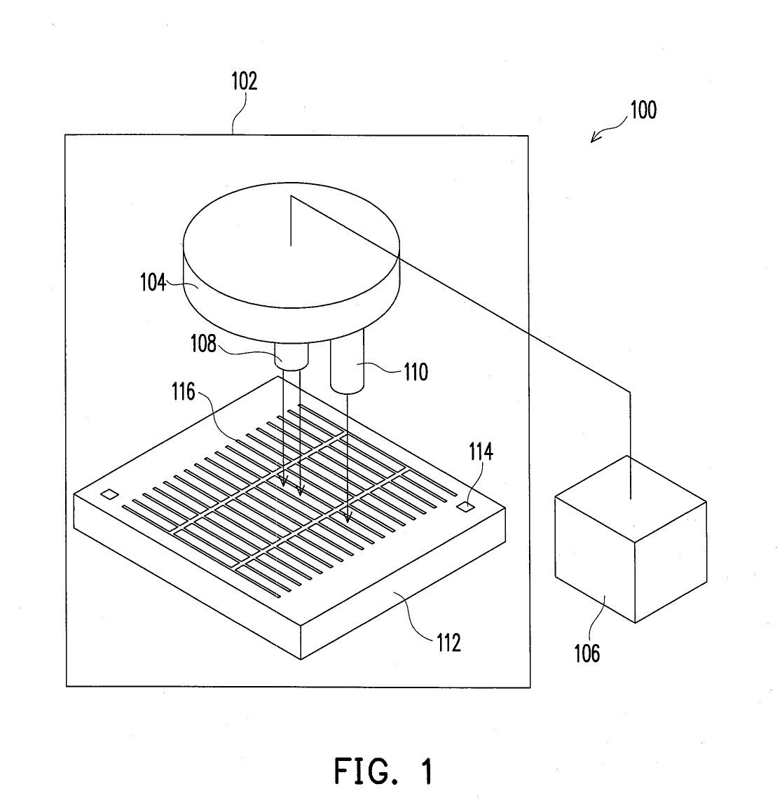

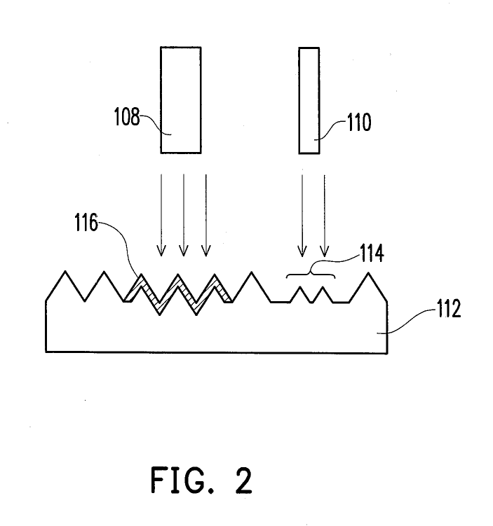

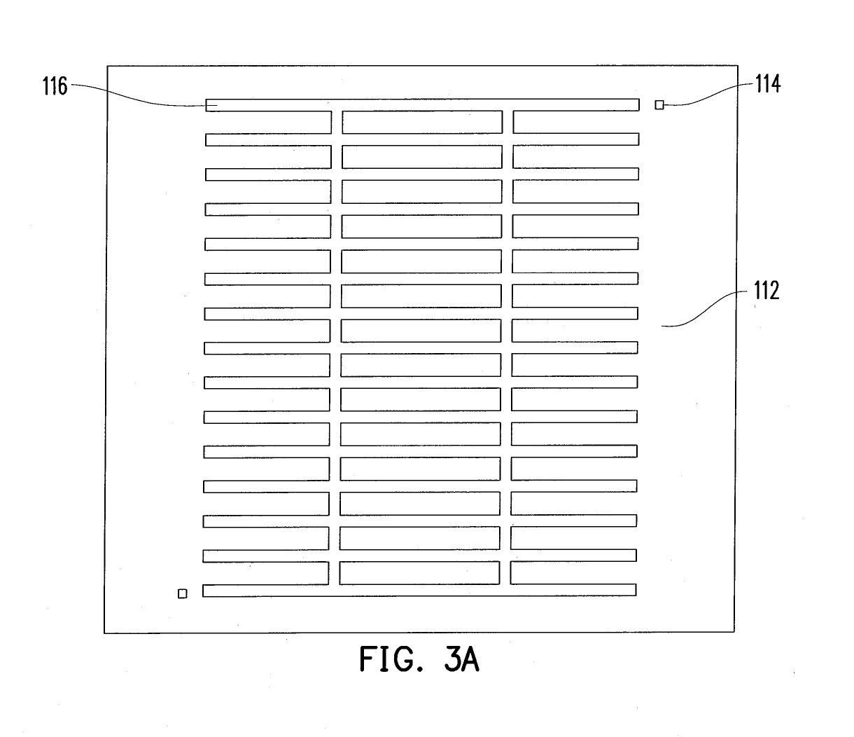

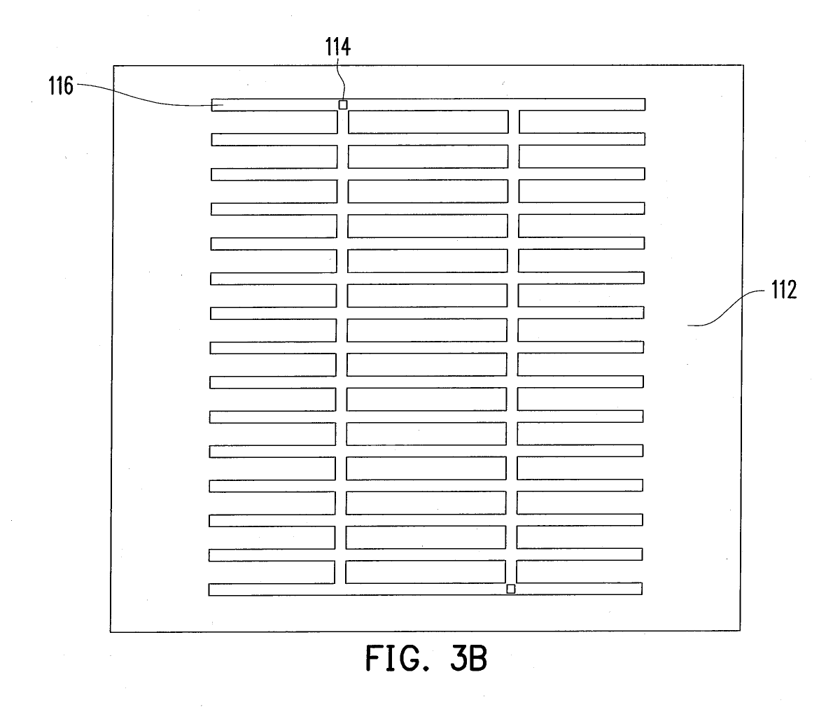

FIG. 1 is a three-dimensional view of an apparatus for manufacturing an electrode of a solar cell according to an embodiment of the invention. FIG. 2 is a cross-sectional view of the apparatus for manufacturing an electrode of a solar cell according to an embodiment of the invention. FIG. 3A is a top view of a solar cell according to an embodiment of the invention. FIG. 3B is a top view of a solar cell according to another embodiment of the invention.

Referring to FIG. 1, the apparatus 100 for manufacturing an electrode of a solar cell has a processing chamber 102, a laser light emitting device 104 and a control device 106.

The processing chamber 102 is used to process a substrate 112. A carrier is, for example, disposed in the processing chamber 102, and the substrate 112 is disposed on the carrier.

The laser light emitting device 104 is disposed in the processing chamber 102. The laser light emitting device 104 may have at least one laser device. In the present embodiment, the laser light emitting device 104 has two laser devices, i.e. a doping laser device 108 and a marking laser device 110.

Referring to FIG. 1 and FIG. 2, the doping laser device 108 is used to emit a doping laser light to perform a laser doping process, so as to form a selective emitter 116 (a heavy doping area) on the substrate 112. The marking laser device 110 is used to emit a marking laser light to perform a laser marking process, so as to form alignment markers 114 on the substrate 112.

In an embodiment, the alignment markers 114 are formed at a peripheral region of the substrate 112. In the present invention, the peripheral region refers to a region on the substrate 112 that is not formed with the selective emitter 116. Referring to FIG. 3A, the alignment markers 114 are formed at a corner region of the substrate 112. Certainly, the alignment markers 114 can also be formed at any unused position on the substrate 112.

In another embodiment, the alignment markers 114 are formed on the selective emitter 116. As shown in FIG. 3B, the alignment markers 114 are formed on intersections of the selective emitter 116. Certainly, the alignment markers 114 can also be formed at any positions of the selective emitter 116. By forming the alignment markers 114 on the selective emitter 116, since a surface light-shielding area of the solar cell is not increased, photoelectric conversion efficiency of the solar cell is not decreased.

The laser light emitting device 104 may also have one laser device or more than two laser devices. When the laser light emitting device 104 has only one laser device, such laser device is used to perform both of the laser doping process and the laser marking process.

The control device 106 is connected to the laser light emitting device 104 to control the laser light emitting device 104 to perform the laser doping process and the laser marking process in the processing chamber 102. The control device 106 is, for example, a computer, etc.

The control device 106 controls the laser light emitting device 104 to first perform the laser marking process and then perform the laser doping process, or the control device 106 controls the laser light emitting device 104 to first perform the laser doping process and then perform the laser marking process, or the control device 106 controls the laser light emitting device 104 to simultaneously perform the laser marking process and the laser doping process.

In the above apparatus for manufacturing the electrode of the solar cell, the laser light emitting device has a function of emitting the doping laser light and the marking laser light. In the same processing chamber, the control device is used to control the laser light emitting device to fabricate the alignment markers and the laser doping area (the selective emitter) through one laser device or different laser devices, so as to avoid relative displacement between the alignment markers and the laser doping area (the selective emitter) and reduce the error of a subsequent screen printing process.

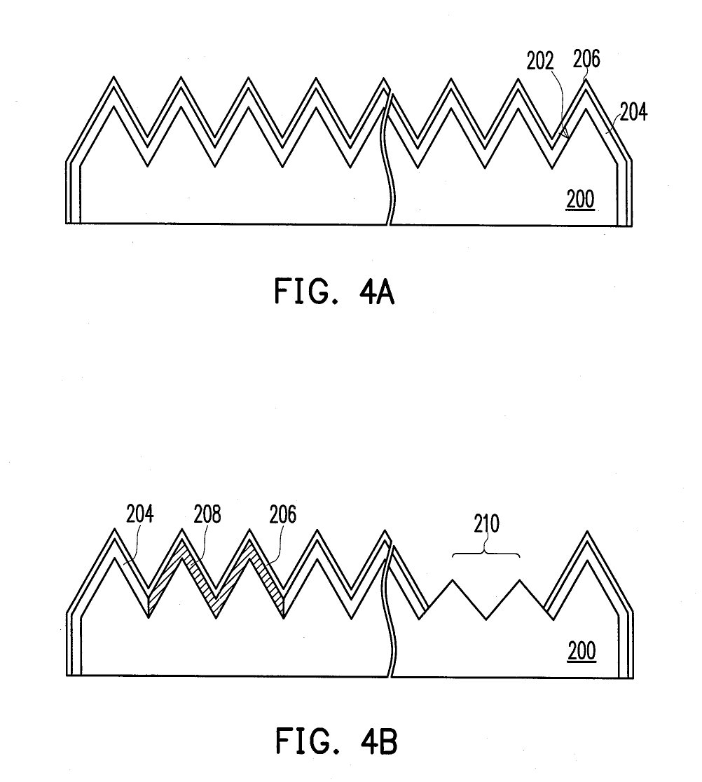

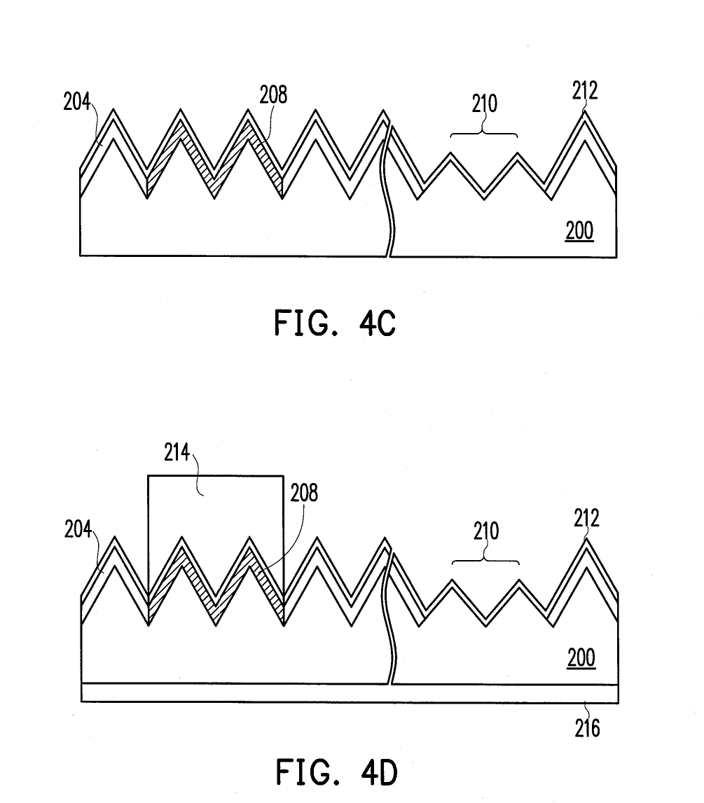

FIGS. 4A-4D are diagrams illustrating a method for manufacturing an electrode of a solar cell according to an embodiment of the invention. In the following description, when the first conductive type is an n-type, the second conductive type is a p-type, and when the second conductive type is the n-type, the first conductive type is the p-type. A p-type substrate and a p-type doped layer, etc. represent that the third group elements in the periodic table are doped, for example, boron (B), gallium (Ga) and indium (In), etc. A n-type substrate and the n-type doped layer, etc. represent that the fifth group elements in the periodic table are doped, for example, phosphorus (P), arsenic (As) and antimony (Sb), etc.

Referring to FIG. 4A, a substrate 200 is provided. The substrate 200 is, for example, a first conductive type substrate. Then, pyramid structures 202 are formed on the surface of the substrate 200. A method of forming the pyramid structures 202 is, for example, to perform an anisotropic etching process.

Then, a second conductive type light doping layer 204 is formed on the surface of the substrate 200. A method of forming the second conductive type light doping layer 204 is, for example, a thermal diffusion method. Then, a second conductive type dopant material layer 206 is formed on the second conductive type light doping layer 204.

When the first conductive type is the p-type and the second conductive type is the n-type, the p-type silicon substrate is disposed in a phosphorus-contained gas (for example, a gas mixture of phosphorus trichloride, nitrogen and oxygen) for heat treatment to form the n-type light doping layer 204. A material of the n-type dopant material layer 206 is, for example, phosphosilicate glass (PSG).

When the first conductive type is the n-type and the second conductive type is the p-type, the n-type silicon substrate is disposed in a boron-contained gas mixture for heat treatment to form the p-type light doping layer 204. A material of the p-type dopant material layer 206 is, for example, borosilicate glass (BSG).

Referring to FIG. 4B, the laser doping process is performed to form the selective emitter 208 (the heavy doping area) on the substrate 200, and the laser marking process is performed to form alignment markers 210 on the surface of the substrate 200. The laser doping process and the laser marking process are performed in the same processing chamber. In the laser doping process, the laser beam is provided to the second conductive type dopant material layer 206 to disperse a second conductive dopant in the second conductive type dopant material layer 206 to the second conductive type light doping layer 204 to form the selective emitter 208 (the second conductive type heavy doping area). The laser marking process is to provide the laser beam to remove a part of the phosphosilicate glass 206 and a part of the substrate 200 to form the alignment markers 210.

In the invention, the laser doping process is performed before the laser marking process is performed, or the laser doping process is performed after the laser marking process is performed, or the laser doping process and the laser marking process are simultaneously performed.

The alignment markers 210 are formed at the peripheral region of the substrate 200, for example, the alignment markers 210 are formed in a diagonal region of the substrate 200. In another embodiment, the alignment markers 210 are formed on the selective emitter 208, for example, the alignment markers 210 can be formed on the outermost selective emitter 208.

Referring to FIG. 4C, the second conductive type dopant material layer 206 is removed, and the second conductive type light doping layer 204 on a sidewall of the substrate 200 is removed. An antireflection layer 212 is formed on the surface of the substrate 200. A method of forming the antireflection layer 212 is, for example, a chemical vapor deposition method. A material of the antireflection layer 212 is, for example, silicon oxynitride or silicon nitride, etc.

Referring to FIG. 4D, an electrode 214 is formed on the surface of the substrate 200, and an electrode 216 is formed on the backside of the substrate 200. The electrode 214 is only located on the selective emitter 208 (the second conductive type heavy doping area). A method of forming the electrode 214 is, for example, to perform an electrode screen printing process to form a silver conductive adhesive film on the selective emitter according to the alignment markers, and then perform a sintering process to electrically connect the electrode 214 and the selective emitter 208 (the second conductive type heavy doping area). The electrode 216 is formed on the backside of the substrate 200. A method of forming the electrode 216 is, for example, to perform the electrode screen printing process to form an aluminium conductive adhesive film on the whole backside of the substrate 200, and then perform the sintering process.

In the aforementioned method for manufacturing the electrodes of the solar cell, the laser doping process and the laser marking process are performed in the same processing chamber, so that the relative displacement between the alignment markers and the laser doping area (the selective emitter) is avoided, so as to reduce the error of the subsequent screen printing process.

In summary, in the method and the apparatus for manufacturing the electrode of the solar cell, relative displacement between the alignment marker and the laser doping area (the selective emitter) is avoided so as to reduce the error of the subsequent screen printing process. Moreover, by forming the alignment markers on the laser doping area, since a surface light shielding area of the solar cell is not increased, the photoelectric conversion efficiency of the solar cell is not decreased. In addition, the method for manufacturing the electrode of the solar cell is simple, which avails increasing a production yield.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A method for manufacturing an electrode of a solar cell, comprising:
performing a laser doping process to form a selective emitter on a substrate;
performing a laser marking process to form an alignment marker on the substrate, wherein the laser doping process and the laser marking process are performed in a same processing chamber; and
performing an electrode screen printing process to form an electrode on the selective emitter according to the alignment marker.

2. The method for manufacturing the electrode of the solar cell as claimed in claim 1, wherein the laser doping process is performed before the laser marking process is performed.

3. The method for manufacturing the electrode of the solar cell as claimed in claim 1, wherein the laser doping process is performed after the laser marking process is performed.

4. The method for manufacturing the electrode of the solar cell as claimed in claim 1, wherein the laser doping process and the laser marking process are simultaneously performed.

5. The method for manufacturing the electrode of the solar cell as claimed in claim 1, wherein the alignment marker is formed at a peripheral region of the substrate.

6. The method for manufacturing the electrode of the solar cell as claimed in claim 1, wherein the alignment marker is formed on the selective emitter.
